(19) United States
(12) Patent Application Publication
(10) Pub. No.: US 2026/0218418 A1
(43) Pub. Date: Jul. 30, 2026

(54) Uniform And Controllable Silicone Doping Of Aluminum Nitride

(71) Applicant: The Regents of The University of Michigan, Ann Arbor, MI (US)

(72) Inventors: Irfan KHAN, Ann Arbor, MI (US); Elaheh AHMADI, Ann Arbor, MI (US)

(73) Assignee: The Regents of The University of Michigan, Ann Arbor, MI (US)

(21) Appl. No.: 19/001,754

(22) Filed: Dec. 26, 2024

Related U.S. Application Data
(60) Provisional application No. 63/617,978, filed on Jan. 5, 2024.

(51) Int. Cl. C30B 31/06; C30B 23/02; C30B 25/18; C30B 25/20; C30B 29/40; H10P 14/20

(52) U.S. Cl. CPC C30B 31/06; C30B 23/025; C30B 25/18; C30B 25/20; C30B 29/403; H10P 14/3416; H10P 14/3442

(57) ABSTRACT

Controllable Si doping in N-polar aluminum nitride (AlN) films grown on single crystal AlN substrate is achieved by plasma assisted molecular beam epitaxy (PAMBE). Through optimization of growth condition, high quality N polar AlN films were obtained at 950° C. However, further studies revealed that silicon incorporation dramatically decreases at such high growth temperature. To enable higher silicon incorporation, a hybrid low temperature and high temperature growth condition was developed by using gallium as surfactant at low temperature growth. By lowering the growth temperature of AlN to 750° C., silicon was incorporated with concentrations as high as 2×10²⁰ cm⁻³ and demonstrated an electron concentration as high as 1×10¹⁹ cm⁻³ at room temperature.

### CROSS-REFERENCE TO RELATED APPLICATIONS

This application claims the benefit and priority of U.S. Provisional Application No. 63/617,978 filed on Jan. 5, 2024. The entire disclosure of the above application is incorporated herein by reference.

### GOVERNMENT CLAUSE

This invention was made with government support under W911NF-22-2-0176 awarded by the Army Research Laboratory-Army Research Office. The government has certain rights in the invention.

### FIELD

The present disclosure relates to uniform and controllable silicon doping of aluminum nitride.

### BACKGROUND

In recent years, aluminum nitride (AlN) has garnered significant attention in the research community due to its excellent electronic properties. Aluminum nitride, which is an ultra-wide bandgap material with direct band gap of 6.2 eV, has high breakdown electric field (12 MV/cm) and high thermal conductivity. In addition, band engineering can be achieved by alloying aluminum nitride with Gallium (Ga), Indium (In) and Scandium (Sc) and 2 d electron gas (2 DEG) is formed at AlGaN/AlN interface due to strong piezoelectric and spontaneous polarization. Furthermore, aluminum nitride has high temperature stability, which is suitable for application in harsh environment. Due to these unique properties aluminum nitride has gained attention as a promising candidate for next generation of high power electronics and optoelectronics application.

N polar III-N has several advantages over metal polar III-N for device application. The N-polar heterostructure possess an inherent wide-bandgap Al(Ga)N back barrier that reduces buffer leakage as well as short-channel effect and results in better confinement of 2 d electron gas. This enhances off-state pinch-off characteristics as well as reduces on-state output conductance. Better backside confinement pushes the 2 d electron gas toward the gate metal, which improves gate capacitance as well as gate control over the channel. Furthermore, the 2 d electron gas in N-polar high electron mobility transistors (HEMTs) can be contacted through the channel layer with narrower bandgap with smaller barrier to electron rather than through wide-bandgap barrier, which is a bottleneck to obtain low resistance ohmic contact in metal polar HEMT. This results in lower ohmic resistance in N-polar heterostructure by utilizing selective area ohmic regrowth. Due to these unique advantages, N polar III-N has become more attractive for next generation high power, high frequency electronic application.

Uniform and controlled n-type doping in aluminum nitride is critical for realization of AlN-based devices for next generation electronic and optoelectronic application. Silicon (Si) has been the most common n-type dopant in aluminum nitride for the last few decades. Although silicon is a shallow donor in GaN, with increase in aluminum content in GaN, silicon ionization energy increases. Silicon dopant in aluminum nitride transforms to a stable DX configuration states near conduction band quenching the doping efficiency of AlN:Si. In addition, with increasing silicon doping, a compensation knee phenomenon was observed. At low silicon doping level, increasing silicon concentrations increases free electrons. But for high silicon doping, an increase in silicon concentrations reduces free electron concentrations. The mechanism of this compensation knee has been attributed to many factors including DX transition, cation vacancies, SiN and cation vacancy-silicon complexes. Some have proposed that VAl+nSiAl complexes play a vital role for the compensation knee behavior in silicon doped aluminum nitride. At low silicon doping, the SiAl and VAl determine the fermi level which increases with increasing silicon doping whereas at high silicon doping, VAl+2SiAl and VAl+3SiAl complexes determine the fermi level that decreases with increasing silicon doping. Furthermore, low threading dislocation density (TDD) AlN films, such as bulk AlN or AlN epitaxially grown on single-crystal AlN substrates, is crucial to obtain high n-type conductivity.

This section provides background information related to the present disclosure which is not necessarily prior art.

### DRAWINGS

The drawings described herein are for illustrative purposes only of selected embodiments and not all possible implementations, and are not intended to limit the scope of the present disclosure.

FIG. 1 depicts an innovative technique for fabricating a semiconductor.

FIGS. 2A and 2B are images of 200 nm thick aluminum nitride grown at 950 degree Celsius with Al flux of 4.7×10⁻⁷ Torr and 5×10⁻⁷ Torr, respectively.

FIGS. 3A-3C are images of 200 nm thick silicon doped aluminum nitride grown at 950 degree Celsius with silicon cell temperature of 1075° C., 1150° C., and 1225° C., respectively.

FIG. 4A is a graph showing SIMS profile of silicon in Si doped aluminum nitride sample indicating extremely low Si incorporation in AlN grown at 950° C.

FIG. 4B is an image of Si doped AlN SIMS stack in FIG. 4A.

FIGS. 5A and 5B illustrate an epilayer structure and a corresponding image of aluminum nitride grown at 750° C. and grown at 950° C., respectively.

FIG. 6A is a graph showing SIMS profile of silicon in Si doped aluminum nitride sample indicating controllable Si incorporation in AlN grown at 750° C.

FIG. 6B is an image of Si doped AlN SIMS stack of FIG. 6A.

FIGS. 7A-7E are images of silicon doped aluminum nitride samples grown at 750° C. with silicon concentrations of 4×10¹⁸ cm⁻³, 3×10¹⁹ cm⁻³, 6×10¹⁹ cm⁻³, 1×1020 cm⁻³, and 2×1020 cm⁻³, respectively.

FIG. 8 is a graph showing room temperature hall electron concentration and hall electron mobility vs silicon doping concentration for Si doped AlN samples grown at 750° C.

FIGS. 9A and 9B are graphs showing temperature dependent hall electron concentration and hall electron mobility, respectively, for Si doped AlN samples grown at 750° C.

Corresponding reference numerals indicate corresponding parts throughout the several views of the drawings.

### DETAILED DESCRIPTION

Example embodiments will now be described more fully with reference to the accompanying drawings.

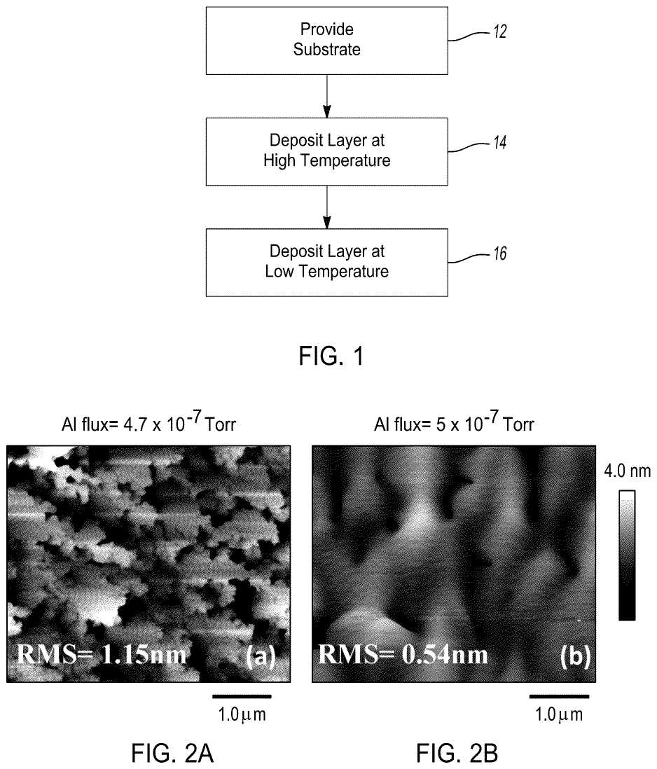

FIG. 1 depicts an example method for fabricating a semiconductor device. As a starting point, a substrate is provided at 12 for the semiconductor device. In the example embodiment described below, the substrate is an N-polar aluminum nitride. Other suitable substrates may include but are not limited to sapphire, silicon carbide, silicon or metal polar aluminum nitride.

Applicant discovered that silicon incorporation into aluminum nitride reduced significantly at high temperatures. To enhance silicon incorporation, a technique was developed of growing high-quality films via hybrid low temperature and high temperature growth conditions. That is, a first layer of aluminum nitride is deposited at 14 on a surface of the substrate at a first temperature, where the first temperature is greater than 900 degrees Celsius. In some embodiments, the first temperature is in the range of 900 to 1,000 degrees Celsius and preferably on the order of 950 degrees Celsius.

A second layer of aluminum nitride is then deposited at 16 on top of the first layer using a surfactant and at a second temperature while concurrently doping the second layer with silicon, where the second temperature is less than 800 degrees Celsius. With gallium as the surfactant, the second temperature is in the range of 700 to 800 degrees Celsius; whereas, with indium as the surfactant, the second temperature is in the range of 600 to 800 degrees Celsius. This method improved the silicon incorporation in aluminum nitride dramatically leading to silicon doping concentration as high as 2×1020 cm−3 and electron concentration as high as 1×1019 cm−3 at room temperature. In the example embodiment, the first and second layers of aluminum nitride are deposited using molecular beam epitaxy although metalorganic vapor-phase epitaxy and other techniques also fall within the broader aspects of this disclosure. While the following description is made with reference to doping with silicon, germanium as well as other n-type dopants are contemplated by this disclosure.

For demonstration purposes, aluminum nitride samples were grown in a Veeco GENXplore MBE system with conventional aluminum and gallium effusion cells and a radio-frequency (RF) plasma source to supply active nitrogen. In an example embodiment, the nitrogen source consisted of ultrahigh-Purity (99.9999%) N2 gas flowing at 0.3 SCCM through the rf-plasma source with 350-W rf power, which corresponded to a growth rate of 2.5 nm/min for GaN films grown in metal rich regime. Commercially available N polar AlN substrate was used for the growth of AlN. Before the growth, the substrate was coated with 500 nm of e-beam evaporated titanium on the backside. After that the substrate was solvent cleaned with four (4) minutes soaking in acetone, methanol and isopropanol to remove all the organic residues from substrate surface. After solvent cleaning, the substrate piece was bonded to a Si wafer with molten In. The prepared substrate was then loaded into the MBE load lock chamber. An hour of baking was performed at 400° C. in the buffer chamber to remove any water prior to transferring the substrate to the growth chamber. During the growth, the substrate temperature was measured and monitored using a thermocouple. The growth was monitored in situ via reflection high-energy electron diffraction (RHEED).

A Veeco Dimension ICON atomic force microscopy (AFM) was employed to characterize the surface morphology and surface roughness of the samples. Secondary ion mass spectrometry (SIMS) was utilized to measure the Si doping concentration and uniformity. Hall electron concentration and hall electron mobility was measured at room temperature by a Ecopia HMS-3000 hall measurement system, with Ti/Al/Ni/Au ohmic contact placed near the corners of 5×5 mm 2 samples in van der pauw configuration. Temperature dependent hall measurement was carried out in van der pauw configuration in Quantum Design's Dynacool Physical Property Measurement System (PPMS).

In an example embodiment, the growth condition of aluminum nitride was optimized at 950° C. Prior to the growth of AlN, in situ surface cleaning was carried out via Al polishing at 950° C. with Al flux of 5×10⁻⁷ Torr to remove the surface oxide. During the Al polishing, the Al shutter was opened for 30 seconds and then closed for 40 seconds to thermally desorb all the Al on the surface. This cycle was repeated 30 times. The Al polishing resulted in a streaky reflection high-energy electron diffraction (RHEED) pattern.

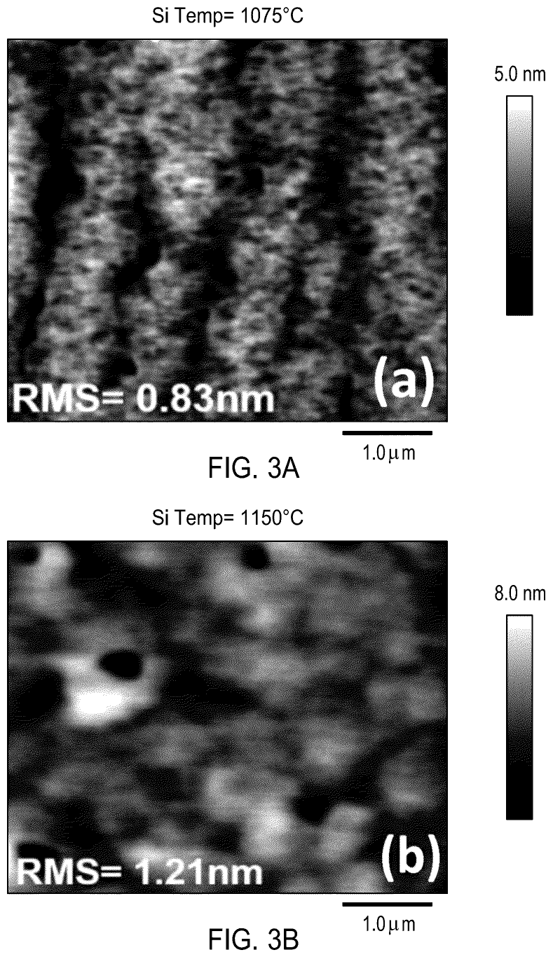

A series of aluminum nitride samples were then grown with Al fluxes 4.7×10⁻⁷ Torr and 5×10⁻⁷ Torr. From the AFM images of these samples presented in FIGS. 2A and 2B, it can be observed that the sample with lower Al flux has higher RMS roughness and lots of pits on the surface; whereas, the sample grown with higher Al flux has excellent surface morphology with low surface roughness and clear step edges indicating a step-flow growth. Hence, the higher flux condition was selected for the subsequent growths of AlN layer at 950° C.

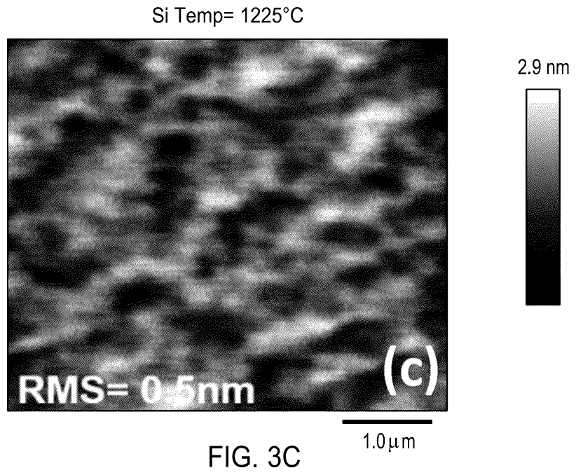

After optimization of AlN growth condition, a series of Si doped AlN samples were grown at 950° C. with Si cell temperature ranging from 1075° C.-1225° C. The AFM images of these Si doped samples displayed in FIGS. 3A-3C revealed relatively smooth surface morphology with low RMS roughness on these samples. However, the samples were measured to be insulating. It is worth mentioning that, in the MBE system, the Si doping of GaN with these Si cell temperatures typically yields Si doping concentrations ranging from 3×10¹⁸ cm⁻3 to 3×10²⁰ cm⁻³.

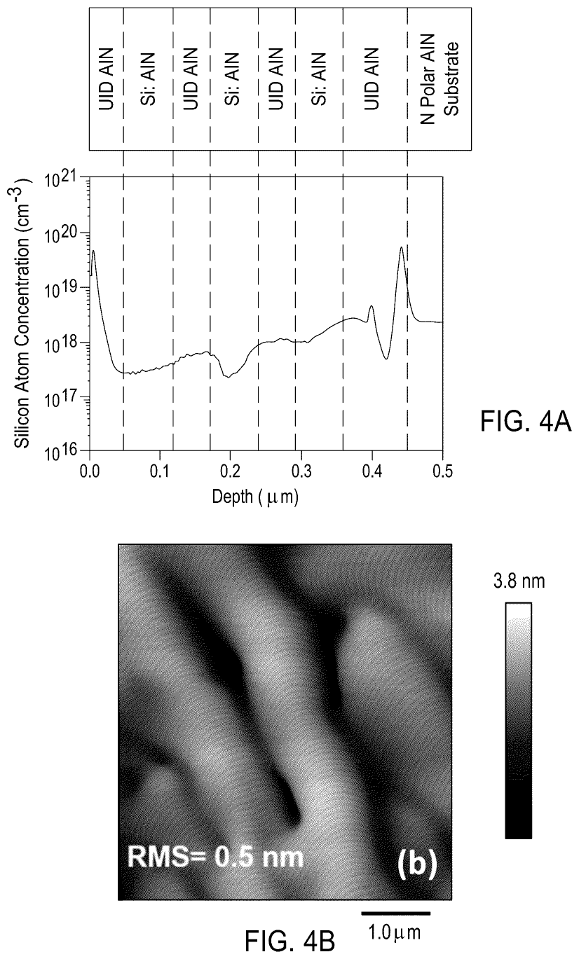

One possible reason for these Si doped AlN samples to be insulating could be very low incorporation of Si in AlN at the growth temperature of 950° C. To verify this hypothesis, an AlN SIMS stack was grown at 950° C. with silicon cell temperatures used in the earlier growths. Although the AFM of the Si doped SIMS stack displayed in FIG. 4B shows excellent surface morphology with clear step edges the SIMS profile presented in FIG. 4A revealed that the Si doping concentration in AlN at 950° C. is very low. Furthermore, no correlation between silicon cell temperature and silicon doping concentration was observed in SIMS profile of Si doped AlN films grown at 950° C.

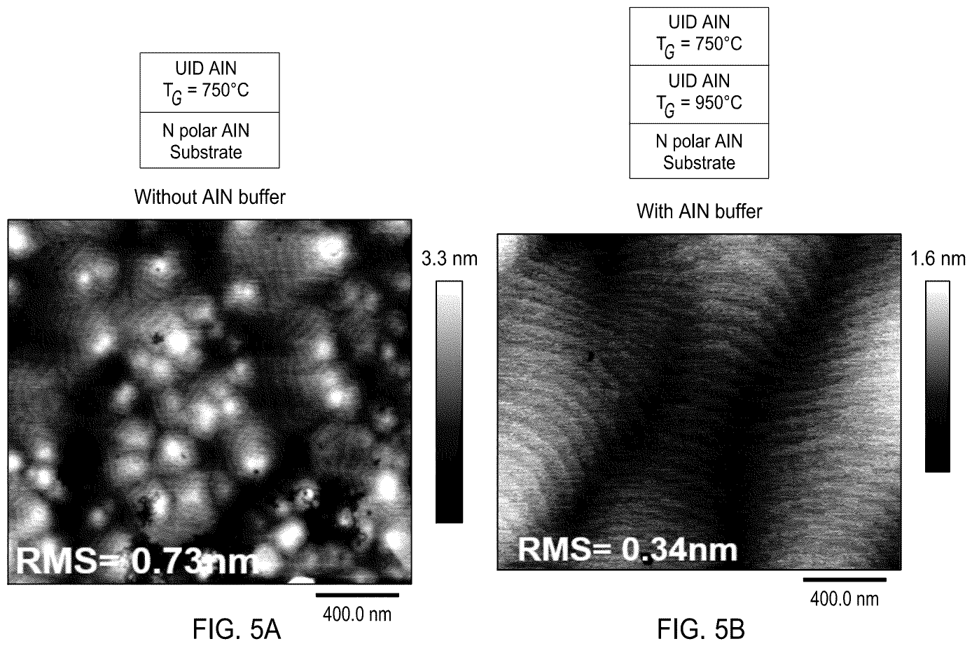

In order to improve silicon incorporation in AlN, a new growth technique was developed to grow AlN at low temperature (750° C.) by using gallium as surfactant (FIG. 5A). Although a relatively smooth surface morphology was obtained, a large number of dislocations were observed (FIG. 5B). To reduce the number of dislocations, a 100 nm thick AlN layer was first grown at 950° C. The substrate temperature was then reduced to 750° C. and AlN film was grown using gallium as surfactant as portrayed in FIG. 5C. As highlighted in FIG. 5D, the inclusion of high temperature AlN buffer layer not only reduced dislocations significantly but also improved surface roughness. This hybrid low temperature and high temperature growth technique by using gallium as surfactant at low temperature growth was then used for the subsequent growth of Si doped AlN.

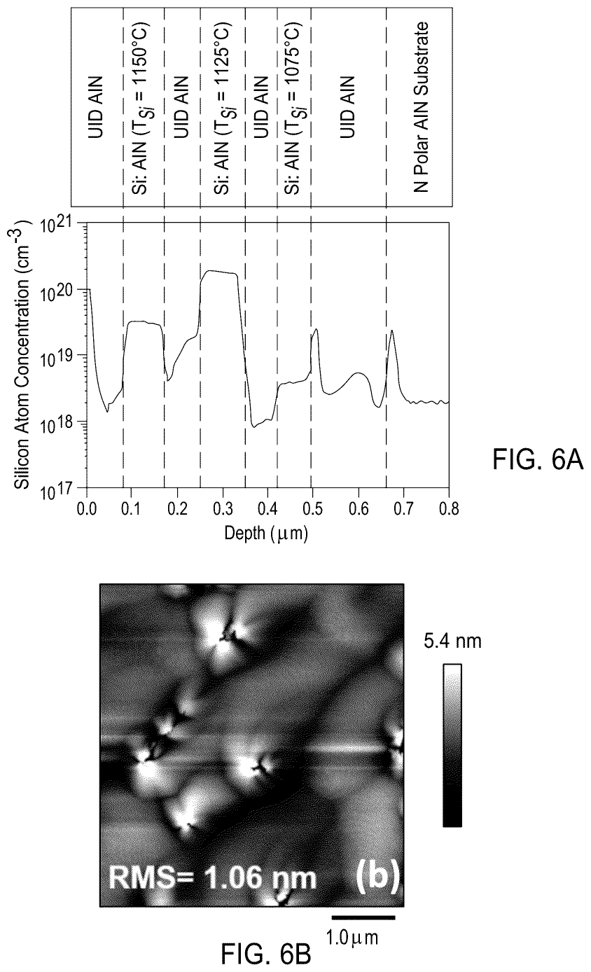

In order to investigate whether the hybrid low temperature high temperature growth technique improves the Si incorporation in AlN, a SIMS stack was grown with AlN layer grown at 950° C. and subsequent Si doped AlN layers grown at 750° C. with Si cell temperatures ranging from 1075° C. to 1225° C. by using gallium as surfactant. The SIMS stack yielded a smooth surface morphology as shown in FIG. 6B and the SIMS profile presented in FIG. 6A highlights significant enhancement of silicon incorporation in AlN with uniform Si doping concentration controlled by silicon cell temperature. This SIMS analysis underscores that the growth temperature of AlN plays a crucial role in efficient Si doping in AlN.

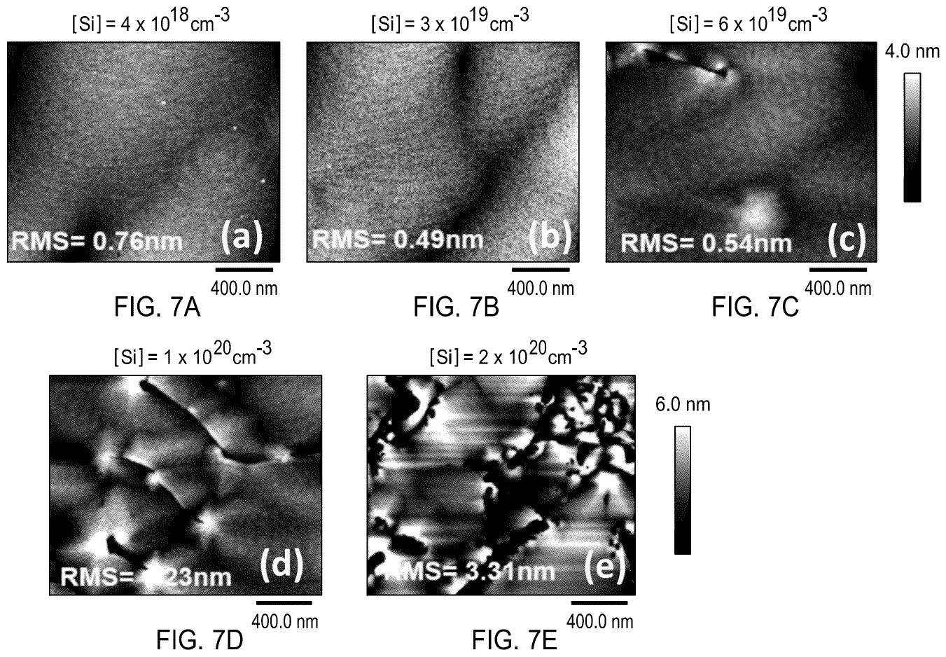

In order to explore the transport properties of Si doped AlN, a series of Si doped AlN samples were grown at 750° C. with different Si cell temperatures ranging from 1075° C.-1225° C. The AFM images of these samples are presented in FIG. 7. The samples with Si doping concentrations of <1×1020 cm⁻3 have very smooth surface morphology which show clear step edges. For the samples doped with 1×1020 cm⁻3 or higher Si concentration, the surface roughness increased significantly due to a large number of pits and cracks which can be attributed to the strain induced through substitution of Si in Al lattice sites.

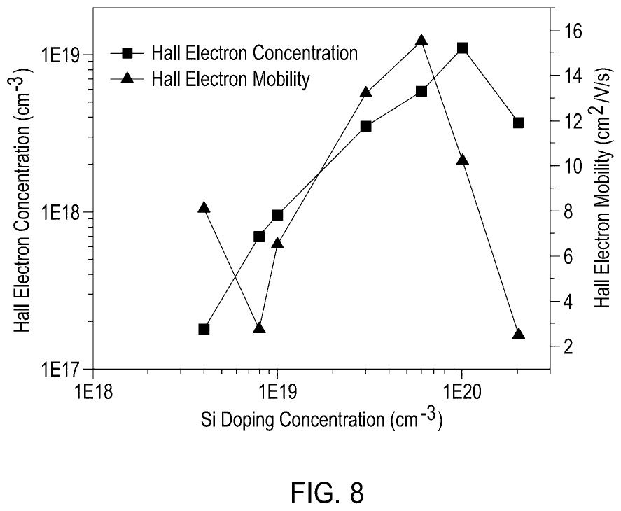

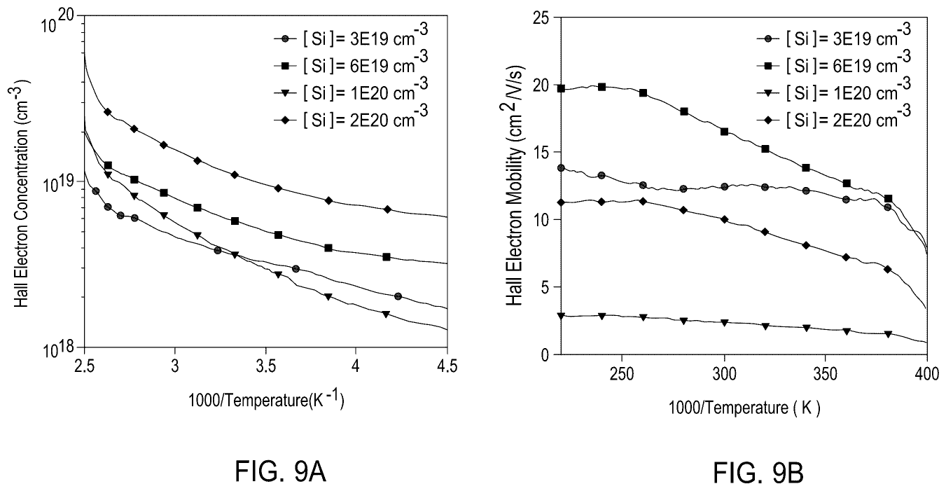

In order to examine the room temperature electron concentration and mobility, hall measurements were performed on these samples at room temperature in van der pauw configuration. From the hall electron concentration highlighted in FIGS. 8A and 8B it can be observed that as the Si doping concentration increases up to 1×1020 cm⁻3 the electron concentration increases. An electron concentration as high as 1×1019 cm⁻3 was obtained for Si doping concentration of 1×1020 cm⁻3 with relatively good mobility of 10 cm2/V·s. Furthermore, beyond 1×1020 cm⁻3 Si doping concentration the electron concentration decreases and the electron mobility also drops which can be attributed to self-compensation of Si dopants in AlN for heavy doping.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method for fabricating a semiconductor device, comprising:
providing a substrate;
depositing a first layer of aluminum nitride on a surface of the substrate at a first temperature, where the first temperature is greater than 900 degrees Celsius; and
depositing a second layer of aluminum nitride on top of the first layer using a surfactant and at a second temperature while concurrently doping the second layer with silicon, where the second temperature is less than 800 degrees Celsius.

2. The method of claim 1 further comprises depositing at least one of the first layer of aluminum nitride or the second layer of aluminum nitride using molecular beam epitaxy.

3. The method of claim 1 wherein the first temperature is on the order of 950 degrees Celsius.

4. The method of claim 3 wherein the first temperature is in the range of 900 to 1,000 degrees Celsius.

5. The method of claim 1 further comprises depositing the second layer of aluminum nitride using gallium as the surfactant.

6. The method of claim 5 wherein the second temperature is on the order of 750 degrees Celsius.

7. The method of claim 5 wherein the second temperature is in the range of 700 to 800 degrees Celsius.

8. The method of claim 1 further comprises depositing the second layer of aluminum nitride using indium as the surfactant.

9. The method of claim 8 wherein the second temperature is in the range of 600 to 800 degrees Celsius.

10. The method of claim 1 further comprises depositing at least one of the first layer of aluminum nitride or the second layer of aluminum nitride using metalorganic vapor-phase epitaxy.

11. The method of claim 1 wherein the substrate is an N-polar aluminum nitride.

12. The method of claim 1 wherein the substrate is one of sapphire, silicon carbide or silicon.

13. A method for fabricating a semiconductor device, comprising:
providing a substrate;
depositing a first layer of aluminum nitride on a surface of the substrate at a first temperature, where the first temperature is greater than 900 degrees Celsius; and
depositing a second layer of aluminum nitride on top of the first layer using gallium as a surfactant and at a second temperature while concurrently doping the second layer with silicon, where the second temperature is in the range of 700 to 800 degrees Celsius.

14. The method of claim 1 further comprises depositing at least one of the first layer of aluminum nitride or the second layer of aluminum nitride using molecular beam epitaxy.

15. The method of claim 1 wherein the first temperature is on the order of 950 degrees Celsius.

16. The method of claim 3 wherein the first temperature is in the range of 900 to 1,000 degrees Celsius.

17. A method for fabricating a semiconductor device, comprising:
providing a substrate;
depositing a first layer of aluminum nitride on a surface of the substrate at a first temperature, where the first temperature is greater than 900 degrees Celsius; and
depositing a second layer of aluminum nitride on top of the first layer using aluminum nitride as a surfactant and at a second temperature while concurrently doping the second layer with silicon, where the second temperature is in the range of 600 to 800 degrees Celsius.

18. The method of claim 1 further comprises depositing at least one of the first layer of aluminum nitride or the second layer of aluminum nitride using molecular beam epitaxy.

19. The method of claim 1 wherein the first temperature is on the order of 950 degrees Celsius.

20. The method of claim 3 wherein the first temperature is in the range of 900 to 1,000 degrees Celsius.
